(19) United States
(12) Patent Application Publication
(10) Pub. No.: US 2008/0142965 A1
(43) Pub. Date: Jun. 19, 2008

(54) Chip package

(75) Inventors: Ching-Shun Wang, Tien-Shui Chen (TW); Chun-Hua Hsia, Tien-Shui Chen (TW); Yu-Heng Liu, Tien-Shui Chen (TW); Yang-Kai Wang, Tien-Shui Chen (TW); Kuang-Yau Teng, Tien-Shui Chen (TW); Ming-Chung Wang, Tien-Shui Chen (TW)

Correspondence Address: DAVIDSON BERQUIST JACKSON & GOWDEY LLP, 4300 WILSON BLVD., 7TH FLOOR, ARLINGTON, VA, 22203, US

(73) Assignee: ADVANCED CONNECTION TECHNOLOGY INC., Tien-Shui Chen (TW)

(21) Appl. No.: 11/785,195

(22) Filed: Apr. 16, 2007

(30) Foreign Application Priority Data
Dec. 18, 2006 (TW) 095147472

(51) Int. Cl. H01L 23/48

(52) U.S. Cl. 257/737

(57) ABSTRACT

A chip package includes: a circuit board formed with conductive traces; a semiconductor chip formed with conductive pads; a bridging member sandwiched between the circuit board and the semiconductor chip and including an elastic dielectric body and spaced apart flexible conductive lines, each of which extends through the elastic dielectric body to contact a respective one of the conductive traces of the circuit board and a respective one of the conductive pads of the semiconductor chip; and a holding member pressing the semiconductor chip against the elastic dielectric body so as to result in pressing action of the elastic dielectric body against the circuit board.

### BACKGROUND OF THE INVENTION

1. Field of the Invention

The invention relates to a chip package, more particularly to a radio frequency identification chip (RFID) package including a circuit board, a RFID chip, and a bridging member sandwiched between the circuit board and the RFID chip.

2. Description of the Related Art

FIG. 1 illustrates a conventional RFID chip package that includes a circuit board 92 with conductive traces 95 formed thereon and serving as an antenna, and a RFID chip 91 mounted on the circuit board 92 and having bonding pads 94 that are electrically connected to the conductive traces 95 through bonding wires 93, respectively. The conventional RFID chip package is disadvantageous in that packaging of the RFID chip 91 is relatively inconvenient and time-consuming.

FIG. 2 illustrates another conventional RFID chip package that includes a circuit board 97 with conductive traces 971 formed thereon, and a RFID flip chip 96 mounted on the circuit board 97 and formed with conductive bumps 98 that are electrically connected to the conductive traces 971. The conventional RFID chip package is disadvantageous in that formation of the bumps 98 is time-consuming and relatively expensive.

### SUMMARY OF THE INVENTION

Therefore, the object of the present invention is to provide a chip package that can overcome the aforesaid drawbacks associated with the prior art.

According to this invention, there is provided a chip package that comprises: a circuit board formed with conductive traces; a semiconductor chip formed with conductive pads; a bridging member sandwiched between the circuit board and the semiconductor chip and including an elastic dielectric body and spaced apart flexible conductive lines, each of which extends through the elastic dielectric body to contact a respective one of the conductive traces of the circuit board and a respective one of the conductive pads of the semiconductor chip; and a holding member pressing the semiconductor chip against the elastic dielectric body so as to result in pressing action of the elastic dielectric body against the circuit board.

### BRIEF DESCRIPTION OF THE DRAWINGS

Other features and advantages of the present invention will become apparent in the following detailed description of the preferred embodiments with reference to the accompanying drawings, of which:

FIG. 1 is a schematic view of a conventional radio frequency identification chip package;

FIG. 2 is a schematic view of another conventional radio frequency identification chip package;

FIG. 3 is a partly sectional view of the first preferred embodiment of a chip package according to the present invention;

FIG. 4 is a perspective view illustrating a configuration of a bridging member of the first preferred embodiment;

FIG. 5 is a perspective view illustrating a configuration of a bridging member of the second preferred embodiment according to the present invention;

FIG. 6 is a fragmentary schematic view to illustrate how the bridging member of the second preferred embodiment is formed;

FIG. 7 is a perspective view illustrating a configuration of a bridging member of the third preferred embodiment according to the present invention; and

FIG. 8 is a fragmentary schematic view to illustrate how the bridging member of the third preferred embodiment is formed.

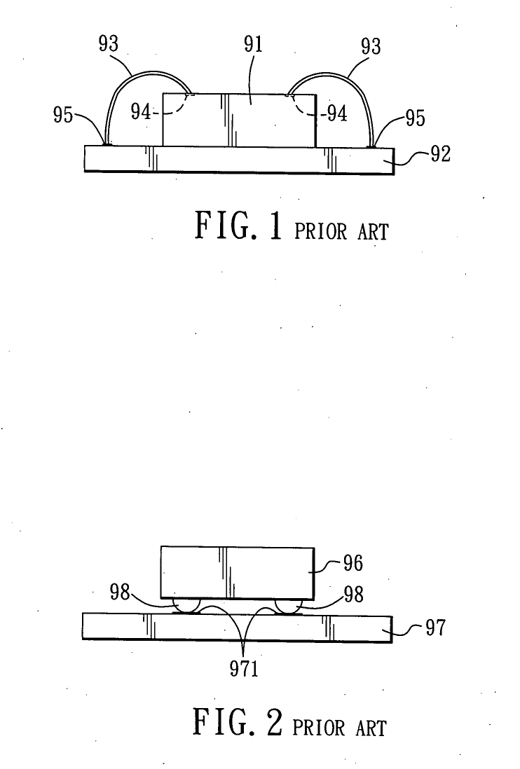

### DETAILED DESCRIPTION OF THE PREFERRED EMBODIMENTS

Before the present invention is described in greater detail with reference to the accompanying preferred embodiments, it should be noted herein that like elements are denoted by the same reference numerals throughout the disclosure.

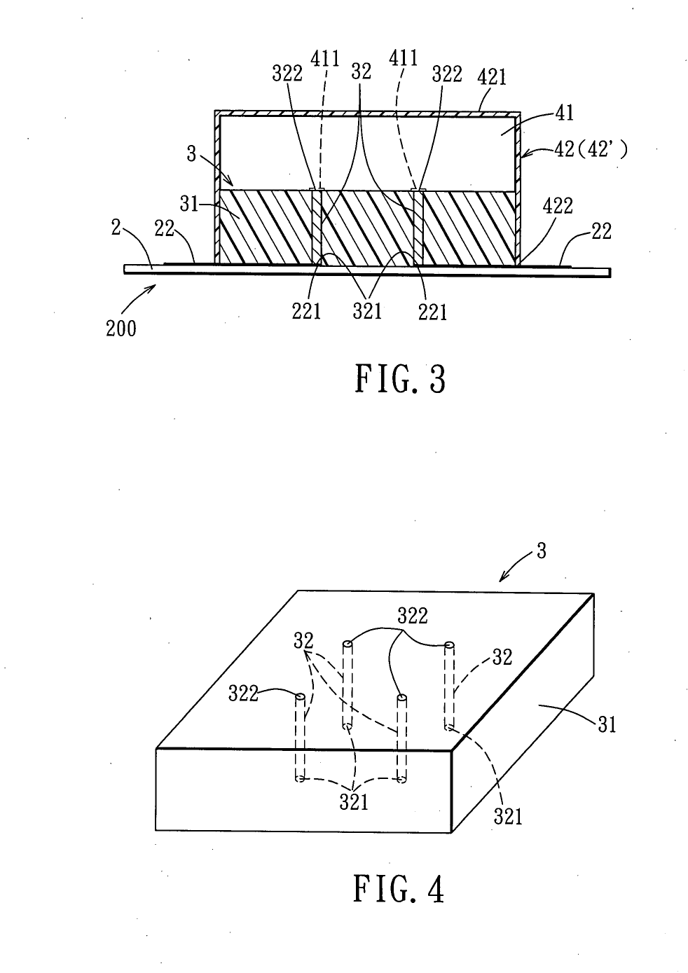

Referring to FIGS. 3 and 4, the first preferred embodiment of a chip package 200 according to the present invention is shown to include: a circuit board 2 formed with conductive traces 22, each of which has a contact end 221; a semiconductor chip 41 formed with conductive pads 411; a bridging member 3 sandwiched between the circuit board 2 and the semiconductor chip 41 and including an elastic dielectric body 31 and spaced apart flexible conductive lines 32, each of which extends through the elastic dielectric body 31 to contact the contact end 221 of a respective one of the conductive traces 22 of the circuit board 2 at one end 321 and a respective one of the conductive pads 411 of the semiconductor chip 41 at the other end 322; and a holding member 42 pressing the semiconductor chip 41 against the elastic dielectric body 31 so as to result in pressing action of the elastic dielectric body 31 against the circuit board 2.

In this embodiment, the holding member 42 includes a casing 42′ that encloses the semiconductor chip 41 and the elastic dielectric body 31 and that has a top wall 421 pressing the semiconductor chip 41 against the elastic dielectric body 31, and a bottom open end 422 secured to the circuit board 2. The casing 42′ has a height slightly less than the overall height of the semiconductor chip 41 and the elastic dielectric body 31 so as to permit the pressing action of the elastic dielectric body 31 against the circuit board 2. Alternatively, the holding member 42 may be in the form of a damper for clamping the semiconductor chip 41, the bridging member 3 and the circuit board 2 together in other embodiments of this invention.

Preferably, the elastic dielectric body 31 is made from a rubber material or a fabric material so as to ensure electrical contact between each conductive line 32 and the respective conductive trace 22 and between each conductive line 32 and the respective conductive pad 411.

The circuit board 2 is preferably in the form of a flexible printed circuit board 2. Each of the conductive lines 32 is preferably in the form of a conductive wire. In this embodiment, the semiconductor chip 41 is a radio frequency identification chip. The conductive traces 22 of the circuit board 2 cooperatively define an antenna unit for radio signal communication with the radio frequency identification chip.

In this embodiment, the elastic dielectric body 31 has a first side that abuts against the circuit board 2, and a second side that is opposite to the first side and that abuts against the semiconductor chip 41. The conductive lines 32 are straight and parallel to each other, and extend in a normal direction relative to the circuit board 2. The ends 321, 322 of each conductive line 32 extend respectively through the first and second sides of the elastic dielectric body 31.

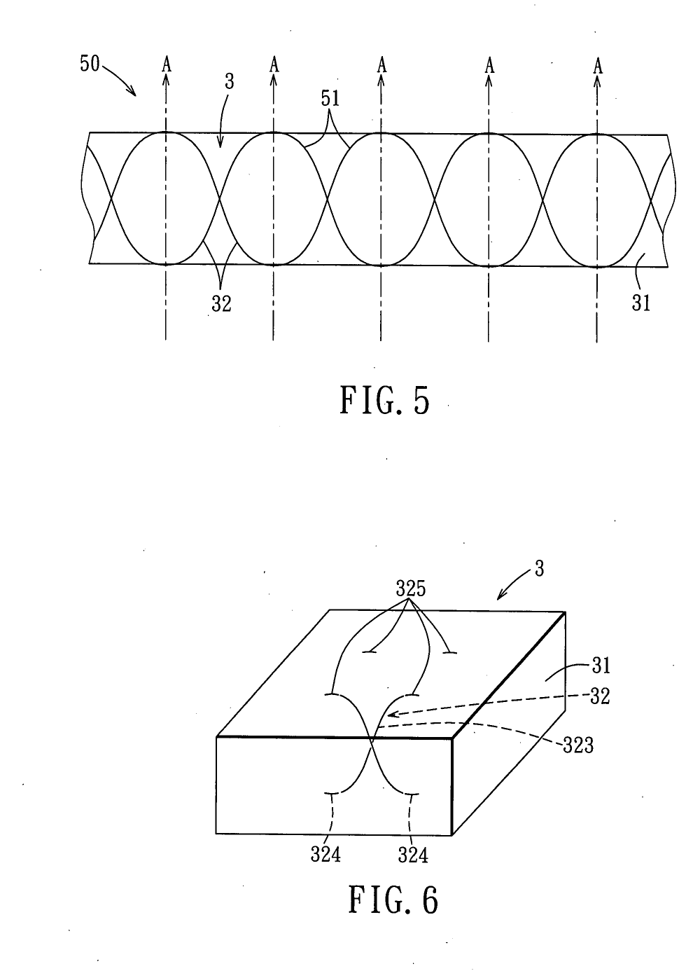

Referring to FIG. 5, the second preferred embodiment of this invention differs from the previous embodiment in the arrangement of the conductive lines 32 in the elastic dielectric body 31. In this embodiment, each conductive line 32 is generally S-shaped, and has a middle segment 323 embedded in the elastic dielectric body 31, a first end segment 324 extending outwardly from one end of the middle segment 323 through the first side of the elastic dielectric body 31 and bent toward the first side of the elastic dielectric body 31, and a second end segment 325 extending outwardly from the other end of the middle segment 323 through the second side of the elastic dielectric body 31 and bent toward the second side of the elastic dielectric body 31. By having a S-shaped configuration for each conductive line 32, the first and second end segments 324, 325 of each of the conductive lines 32 can be offset from each other in the normal direction normal to the circuit board 2. In addition, each two adjacent conductive lines 32 are arranged in a cross manner. As such, the relative position between each conductive pad 411 and the contact end 221 of the respective conductive trace 22 (see FIG. 3) is not limited to a vertically aligned manner and can be varied based on actual requirements.

FIG. 6 illustrates how the bridging member 3 of the second preferred embodiment is formed. During manufacture, a large piece of an elastic dielectric fabric material 50 embedded with a plurality of wave-like structured conductive wires 51 is prepared, followed by cutting the elastic dielectric fabric material 50 along the cutting lines (A) so as to form the bridging member 3 of FIG. 5.

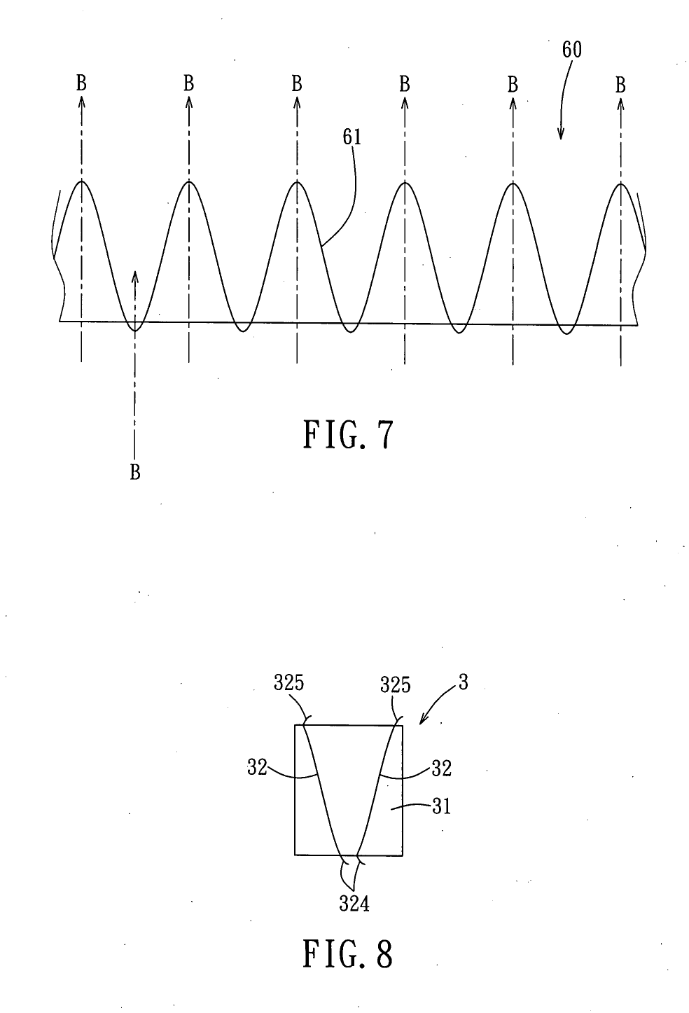

Referring to FIG. 7, the third preferred embodiment of this invention differs from the previous embodiments in the arrangement of the conductive lines 32 in the elastic dielectric body 31. In this embodiment, each two adjacent ones of the conductive lines 32 diverge from one side of the elastic dielectric body 31 to the other side of the elastic dielectric body 31. The first end segments 324 of each two adjacent ones of the conductive lines 32 are bent in the same direction toward said side of the elastic dielectric body 31. The second end segments 325 of each two adjacent ones of the conductive lines 32 are bent in the same direction toward the other side of the elastic dielectric body 31.

FIG. 8 illustrates how the bridging member 3 of the third preferred embodiment is formed. During manufacture, a large piece of an elastic dielectric rubber material 60 embedded with a plurality of V-shaped wave-like structured conductive wires 61 (only one is shown) is prepared, followed by cutting the elastic dielectric rubber material 60 along the cutting lines (B) and bending the end segments 324, 325 of the conductive lines 32 thus formed so as to form the bridging member 3 of FIG. 7.

With the inclusion of the bridging member 3 in the chip package 200 of this invention, the aforesaid drawbacks associated with the prior art can be eliminated.

While the present invention has been described in connection with what are considered the most practical and preferred embodiments, it is understood that this invention is not limited to the disclosed embodiments but is intended to cover various arrangements included within the spirit and scope of the broadest interpretation so as to encompass all such modifications and equivalent arrangements.

1. A chip package comprising:
a circuit board formed with conductive traces;
a semiconductor chip formed with conductive pads;
a bridging member detachably disposed and sandwiched between said circuit board and said semiconductor chip and including a separately formed elastic dielectric body in which spaced apart flexible conductive lines have been formed so as to extend, through said elastic dielectric body to contact a respective one of said conductive traces of said circuit board and a respective one of said conductive pads of said semiconductor chip; and
a holding member pressing said semiconductor chip against said elastic dielectric body so as to compress said elastic dielectric body against said circuit board.

2. The chip package as claimed in claim 1, wherein said holding member includes a casing that encloses said semiconductor chip and said elastic dielectric body, a top wall compressing said semiconductor chip against said elastic dielectric body, and an open a bottom end secured to said circuit board.

3. The chip package as claimed in claim 1, wherein said elastic dielectric body is made from a rubber material.

4. The chip package as claimed in claim 1, wherein said elastic dielectric body is made from a fabric material.

5. The chip package as claimed in claim 1, wherein said circuit board is in the form of a flexible printed circuit board.

6. The chip package as claimed in claim 1, wherein each of said conductive lines is in the form of a conductive wire.

7. The chip package as claimed in claim 1, wherein said elastic dielectric body has a first side that abuts against said circuit board, and a second side opposite to said first side and which abuts against said semiconductor chip, each of said conductive lines having a middle segment embedded in said elastic dielectric body, a first end segment extending outwardly from said middle segment through said first side and bent toward said first side and a second end segment extending outwardly from said middle segment through said second side and bent toward said second side.

8. The chippackage as claimed in claim 7, wherein said first and second end segments are offset from each other in a normal direction normal to said circuit board.

9. The chip package as claimed in claim 1, wherein each of two adjacent ones of said conductive lines are arranged in a cross manner within the elastic dielectric body.

10. The chip package as claimed in claim 1, wherein said semiconductor chip is a radio frequency identification chip, said conductive traces of said circuit board cooperatively defining an antenna unit for radio signal communication with said radio frequency identification chip.
